(19) United States
(12) Patent Application Publication
(10) Pub. No.: US 2009/0057841 A1
(43) Pub. Date: Mar. 5, 2009

(54) WAFER

(75) Inventor: Kazuma SEKIYA, Tokyo (JP)

Correspondence Address: GREENBLUM & BERNSTEIN, P.L.C., 1950 ROLAND CLARKE PLACE, RESTON, VA, 20191, US

(73) Assignee: DISCO CORPORATION, Tokyo (JP)

(21) Appl. No.: 12/199,895

(22) Filed: Aug. 28, 2008

(30) Foreign Application Priority Data
Sep. 4, 2007 (JP) 2007-228812

(51) Int. Cl. H01L 23/544

(52) U.S. Cl. 257/619; 257/E23.179

(57) ABSTRACT

A wafer having a device region, where a plurality of devices is formed, and an outer peripheral surplus region, which surrounds the device region, on the face of a circular wafer substrate is disclosed. A chamfered portion whose cross-sectional shape defines an arc-shaped surface in a range from the face to the back of the wafer substrate is formed in an outer peripheral end portion of the outer peripheral surplus region of the wafer substrate. A flat surface orthogonal to the face and the back is formed in the chamfered portion as a mark showing the crystal orientation of the wafer substrate. An identification code for specifying the wafer substrate is printed on the flat surface.

### FIELD OF THE INVENTION

This invention relates to a wafer, such as a semiconductor wafer or the like, in which devices, such as IC's, LSI's or the like, are formed on the face of a wafer substrate.

### DESCRIPTION OF THE PRIOR ART

In a semiconductor device manufacturing process, a plurality of regions is sectioned by division-scheduled lines, called streets, which are arranged in a lattice pattern on the face of a nearly disk-shaped wafer substrate. Devices, such as IC's, LSI's or the like, are formed in these sectioned regions to constitute a semiconductor wafer. The so constituted semiconductor wafer is cut along the streets, whereby the regions having the devices formed therein are divided to produce the individual devices. An optical device wafer having a gallium nitride-based compound semiconductor or the like laminated on the surface of a sapphire substrate is also cut along the streets, and divided thereby into individual optical devices such as light emitting diodes and laser diodes. These devices are widely used for electrical equipment.

The wafer to be divided in the above-described manner has a back formed in a predetermined thickness by grinding or etching before being cut along the streets. To achieve the light weight and compactness of electrical equipment, demands have been made in recent years that the wafer be formed in a thickness of 50 μm or less.

If the wafer is formed in a thickness of 50 μm or less, however, the problem arises that the wafer is apt to be damaged, presenting difficulty in handling, such as transport, of the wafer.

To solve the above problem, JP-A-2007-19461 discloses a wafer processing method which grinds a region in the back of the wafer corresponding to the device region to bring the thickness of the device region to a predetermined thickness, and also to leave an outer peripheral portion in the back of the wafer, thereby forming an annular reinforcing portion, thus making it possible to form the wafer having rigidity.

However, a notch showing the crystal orientation of the wafer is formed in the outer periphery of the wafer. Even when the region in the back of the wafer corresponding to the device region is ground to leave the outer peripheral portion in the back of the wafer, thereby forming the annular reinforcing portion, the notch portion becomes extremely thin, making it difficult to ensure sufficient strength.

To solve the above-mentioned problem, JP-A-2007-189093 discloses a wafer in which a flat surface orthogonal to the face and back of the wafer is formed, as a mark showing the crystal orientation of the wafer, in a chamfered portion comprising an arc-shaped surface formed in the outer peripheral surface of the wafer.

On the other hand, an identification code comprising a bar code or the like for specifying the wafer during the manufacturing process is printed on the wafer. This identification code is printed on the face, back or outer peripheral surface of the wafer, as disclosed in JP-A-11-135390.

If the identification code is printed on the back of the wafer, however, the problem occurs that the printed identification code disappears when the back of the wafer is ground in order to form the wafer in a predetermined thickness.

If the identification code is printed on the face of the wafer, on the other hand, the problem occurs that the region where devices are to be formed is limited and, if a protective tape, called a BG tape, is stuck to the face of the wafer during grinding of the back of the wafer for forming the wafer in a predetermined thickness, the identification code cannot be recognized.

If the identification code is printed on the outer peripheral surface of the wafer, it is difficult to print the identification code, and the identification code may be erroneously recognized when read, because the chamfered portion of the arc-shaped surface is formed in the outer peripheral surface of the wafer.

If the identification code is printed on an orientation flat formed in the outer periphery of the wafer to indicate the crystal orientation, the above problem is resolved. However, the wafer provided with the orientation flat is problematical in terms of productivity, because of a decrease in the region where the devices are formed. Particularly when the region in the back of the wafer corresponding to the device region is ground to make the thickness of the device region into a predetermined thickness, and leave the outer peripheral portion in the back of the wafer, thereby forming the annular reinforcing portion, the annular reinforcing portion needs to be formed in a range not reaching the orientation flat. This means that the device region becomes narrow, and the number of devices produced is decreased.

### SUMMARY OF THE INVENTION

It is an object of the present invention to provide a wafer in which an identification code for specifying the wafer does not disappear upon grinding of its back, which is not limited in the device region, and which enables the printed identification code to be read without being erroneously recognized.

According to the present invention, for attaining the above object, there is provided a wafer having a device region, where a plurality of devices is formed, and an outer peripheral surplus region, which surrounds the device region, on the face of a circular wafer substrate,

wherein a chamfered portion whose cross-sectional shape defines an arc-shaped surface in a range from the face to the back of the wafer substrate is formed in an outer peripheral end portion of the outer peripheral surplus region of the wafer substrate,

a flat surface orthogonal to the face and the back is formed in the chamfered portion as a mark showing the crystal orientation of the wafer substrate, and

an identification code for specifying the wafer substrate is printed on the flat surface.

Preferably, the identification code is printed on the flat surface in a region between the center and the face side in a thickness direction of the wafer substrate.

In the wafer according to the present invention, the flat surface, as the crystal orientation recognition mark, is formed in the chamfered portion formed in the outer peripheral end portion of the outer peripheral surplus region in the wafer substrate. Compared with a notch or an orientation flat which is a conventional crystal orientation recognition mark, this flat surface needs extremely shallow depth of cut from the outer peripheral surface. Thus, even if the device region is broadened, the width of the outer peripheral surplus region can be fully ensured. Since the device region can thus be broadened, the number of devices produced can be increased. Moreover, the flat surface, as the crystal orientation recognition mark, defines a surface orthogonal to the face and the back of the wafer substrate. As a result, the flat surface unerringly reflects a light beam entering sideways, so that it can be reliably recognized, and can fully function as the crystal orientation recognition mark. Furthermore, since the identification code for specifying the wafer substrate is printed on the flat surface, its printing is easy, and the printed identification code is not erroneously recognized when read. Besides, the identification code for specifying the wafer substrate is printed on the flat surface as the crystal orientation recognition mark formed in the chamfered portion formed in the outer peripheral end portion of the outer peripheral surplus region of the wafer substrate. Thus, the identification code does not disappear even when the back of the wafer substrate is ground.

### BRIEF DESCRIPTION OF THE DRAWINGS

FIG. 1 is a perspective view of a semiconductor wafer as a wafer constituted by the present invention.

FIGS. 2(a) and 2(b) are, respectively, a sectional view and a side view showing, on an enlarged scale, essential parts of the semiconductor wafer shown in FIG. 1.

FIG. 3 is a perspective view showing a state in which a protective member is stuck to the face of the semiconductor wafer shown in FIG. 1.

FIG. 4 is a perspective view of a grinding apparatus for grinding the back of the semiconductor wafer shown in FIG. 1.

FIG. 5 is an explanatory drawing of a reinforcing portion forming step to be performed by the grinding apparatus shown in FIG. 4.

FIG. 6 is a sectional view of the semiconductor wafer which the reinforcing portion forming step shown in FIG. 5 is executed.

FIG. 7 is a perspective view of the semiconductor wafer which the reinforcing portion forming step shown in FIG. 5 is executed.

FIG. 8 is a perspective view of the semiconductor wafer which the reinforcing portion forming step shown in FIG. 5 is executed after the back of the semiconductor wafer shown in FIG. 1 is ground to reduce the thickness in half.

### DETAILED DESCRIPTION OF THE PREFERRED EMBODIMENTS

Preferred embodiments of the wafer constituted according to the present invention will be described in detail by reference to the accompanying drawings.

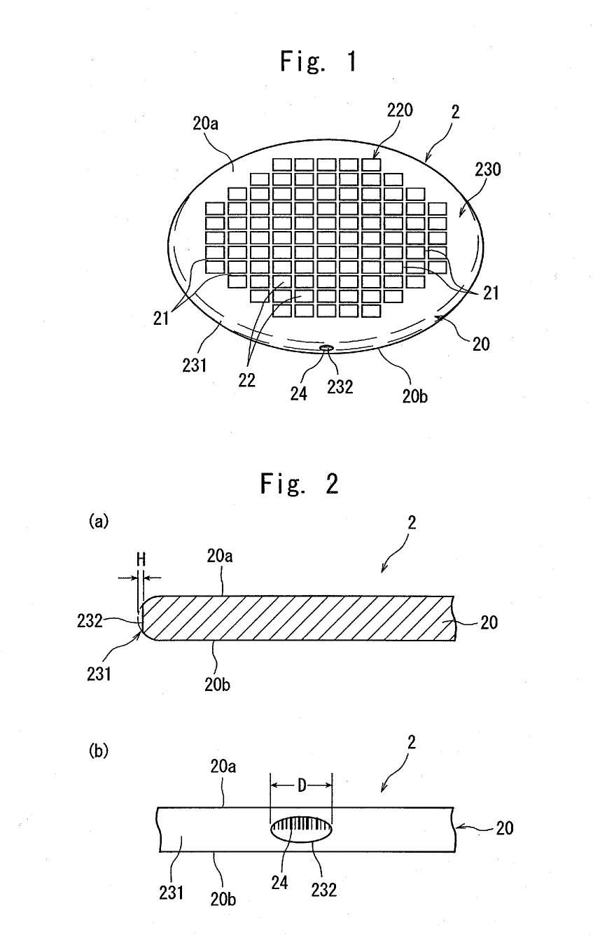

FIG. 1 shows a perspective view of a semiconductor wafer as a wafer constituted by the present invention. A semiconductor wafer 2 shown in FIG. 1 is, for example, a wafer substrate 20 comprising silicon having a thickness of 700 μm on the face 20a of which a plurality of streets 21 is arranged in a lattice pattern, and devices 22, such as IC's, LSI's or the like, are formed in a plurality of regions sectioned by the plurality of streets 21. The so configured wafer substrate 20 is furnished with a device region 220 where the plurality of devices 22 is formed, and an outer peripheral surplus region 230 surrounding the device region 220. A chamfered portion 231, whose sectional shape is an arc-shaped surface in a range from the face 20a to the back 20b of the wafer substrate 20, as shown in FIG. 2(a), is formed at an outer peripheral end portion of the wafer substrate 20, namely, the outer peripheral end portion of the outer peripheral surplus region 230, in order to prevent the occurrence of cracking or chipping due to an impact caused inadvertently. In this chamfered portion 231, a flat surface 232, as a crystal orientation recognition mark showing the crystal orientation of the wafer substrate 20, is formed at a predetermined location as shown in FIG. 2(b).

The flat surface 232, as the crystal orientation recognition mark, is formed in the range of the chamfered portion 231 formed in the outer peripheral end portion of the outer peripheral surplus region 230 in the wafer substrate 20, and is formed to be orthogonal to the face 20a and the back 20b of the wafer substrate 20. This flat surface 232 takes an elliptic shape having a major diameter (D) of about 10 mm at a position where the depth (H) from the outermost periphery is 0.5 mm, for example, when the outer diameter of the wafer substrate 20 is 200 mm. As noted here, the flat surface 232, as the crystal orientation recognition mark, is formed in the range of the chamfered portion 231 formed in the outer peripheral end portion of the outer peripheral surplus region 230 in the wafer substrate 20. This flat surface 232 has extremely shallow depth of cut from the outer peripheral surface in comparison with a notch or an orientation flat which is a conventional crystal orientation recognition mark. Thus, even if the device region 220 is rendered broad, a sufficient width of the outer peripheral surplus region 230 can be ensured. Since the device region 220 can thus be broadened, the number of the devices produced can be increased. Moreover, the flat surface 232, as the crystal orientation recognition mark, defines a surface orthogonal to the face 20a and the back 20b of the wafer substrate 20. As a result, the flat surface 232 unerringly reflects a light beam entering sideways, so that it can be reliably recognized, and can fully function as the crystal orientation recognition mark. The above-mentioned plurality of devices 22 is formed on the face 20a of the wafer substrate 20 having the flat surface 232 formed as the crystal orientation recognition mark in this manner and the streets 21 in a lattice pattern are formed so as to be parallel to or perpendicular to the flat surface 232.

An explanation will be offered for an embodiment of a method for forming the flat surface 232, as the crystal orientation recognition mark, formed at the outer peripheral end portion of the wafer substrate 20, namely, the outer peripheral end portion of the outer peripheral surplus region 230.

The wafer substrate 20 is produced by slicing a columnar ingot, comprising a semiconductor material such as silicon or the like., into round slices. At a predetermined location in the circumferential direction where the crystal orientation recognition mark corresponding to crystal orientation on the outer peripheral surface of the ingot before slicing should be formed, a flat surface extending in the form of a strip along the axial direction is formed in a predetermined width (in the above-mentioned example, approximately 10 mm). Then, the ingot is sliced to form a circular wafer substrate, whereafter the outer peripheral end portion of the wafer substrate is chamfered to form the chamfered portion 231 having an arc-shaped cross sectional shape. As a result, the strip-shaped flat surface formed on the outer peripheral surface of the circular wafer substrate becomes elliptic in form.

The resulting flat surface 232, as the crystal orientation recognition mark, formed at the outer peripheral end portion of the wafer substrate 20, namely, the outer peripheral end portion of the outer peripheral surplus region 230 is printed with an identification code 24 comprising a bar code or the like, for specifying the wafer substrate, as shown in FIG. 2(b), by a well-known printing method. Since the identification code 24 is thus printed on the flat surface 232, its printing is easy, and the printed identification code 24 is not erroneously recognized when read. Furthermore, the identification code 24 is desirably printed on the flat surface 232 in a region between the center and the face 20a in the thickness direction of the wafer substrate 20, as shown in FIG. 2(b).

In the foregoing manner, the identification code 24 for specifying the wafer is printed on the flat surface 232, as the crystal orientation recognition mark, formed at the outer peripheral end portion of the wafer substrate 20, namely, the outer peripheral end portion of the outer peripheral surplus region 230. Then, the aforementioned plurality of devices 22 is formed on the face 20a of the wafer substrate 20.

Next, an explanation will be offered for a processing method for grinding all the regions corresponding to the device region 220 at the back 20b of the wafer substrate 20 of the semiconductor wafer 2, constituted as above, to impart a predetermined thickness, and also form an annular reinforcing portion in the region of the back 20b corresponding to the outer peripheral surplus region 230.

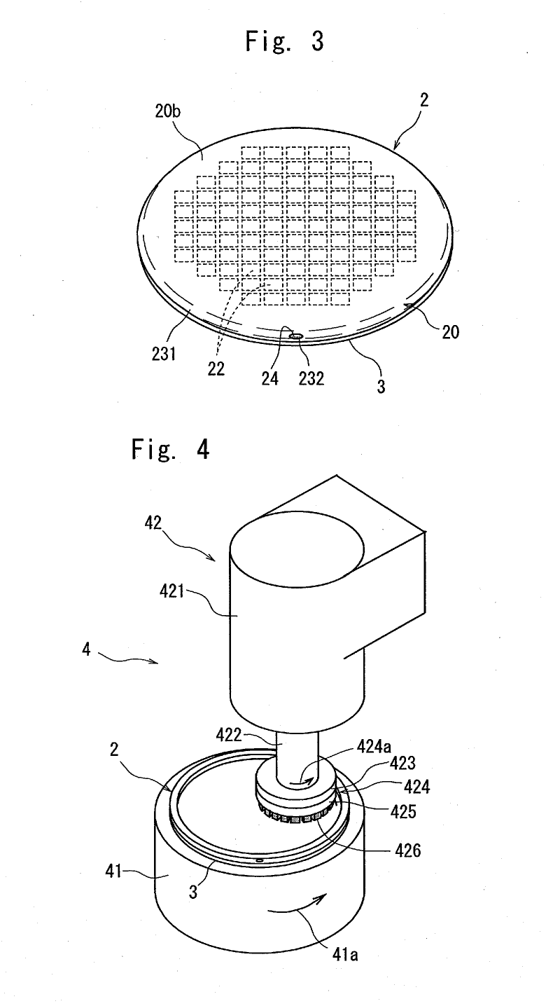

As shown in FIG. 3, a protective member 3 is stuck to the face 20a of the wafer substrate 20 of the semiconductor wafer 2 (a protective member sticking step). Thus, the semiconductor wafer 2 has the back 20b of the wafer substrate 20 exposed.

After the protective member sticking step is performed, a reinforcing portion forming step is carried out for grinding the regions in the back 20b of the wafer substrate 20 corresponding to the device region 220 to render the thickness of the device region 220 a predetermined thickness, and leave the region in the back 20b of the wafer substrate 20 corresponding to the outer peripheral surplus region 230, thereby forming an annular reinforcing portion. This reinforcing portion forming step is carried out by a grinding apparatus shown in FIG. 4.

The grinding apparatus 4 shown in FIG. 4 comprises a chuck table 41 for holding a wafer as a workpiece, and a grinding means 42 for grinding the surface (the surface to be processed) of the wafer held by the chuck table 41. The chuck table 41 suction-holds the wafer on its upper surface, and is rotated in a direction indicated by an arrow 41a in FIG. 4. The grinding means 42 is equipped with a spindle housing 421, a rotating spindle 422 rotatably supported by the spindle housing 421 and rotated by a rotational drive mechanism which is not shown, a mounter 423 mounted at the lower end of the rotating spindle 422, and a grinding wheel 424 attached to the lower surface of the mounter 423. The grinding wheel 424 comprises a disk-shaped base 425, and a grindstone 426 mounted annularly on the lower surface of the base 425, and the base 425 is mounted on the lower surface of the mounter 423.

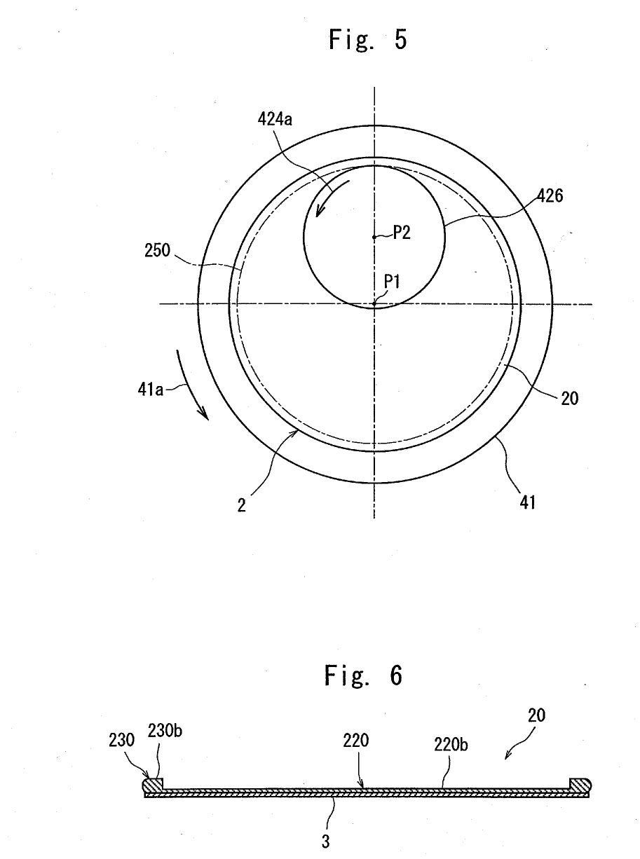

To perform the reinforcing portion forming step using the above-described grinding apparatus 4, the protective member 3 of the semiconductor wafer 2 transported by a wafer carry-in means which is not shown is placed on the upper surface (a holding surface) of the chuck table 41, and the semiconductor wafer 2 is suction-held on the chuck table 41. Here, the relationship between the semiconductor wafer 2 held by the chuck table 41 and the annular grindstone 426 constituting the grinding wheel 424 is explained by reference to FIG. 5. The center of rotation, P1, of the chuck table 41 and the center of rotation, P2, of the annular grindstone 426 are eccentric with respect to each other. The outer diameter of the annular grindstone 426 is set at a dimension which is smaller than the diameter of a borderline 250 between the device region 220 and the surplus region 230 of the wafer substrate 20 constituting the semiconductor wafer 2, but is larger than the radius of the borderline 250. The annular grindstone 426 is adapted to pass the center P1 of rotation of the chuck table 41 (i.e., the center of the semiconductor wafer 2).

Then, while the chuck table 41 is rotated at 300 rpm in the direction indicated by the arrow 41a, the grinding wheel 424 is rotated at 6000 rpm in a direction indicated by an arrow 424a, as shown in FIGS. 4 and 5, and the grinding wheel 424 is moved downward to bring the grindstone 426 into contact with the upper surface (the back) of the wafer substrate 20. Then, the grinding wheel 424 is grindingly fed downward by a predetermined amount at a predetermined grinding feed speed. As a result, in the back of the wafer substrate 20, the region corresponding to the device region 220 is ground away to form a circular concave portion 220b of a predetermined thickness (e.g., 30 μm), and also leave the region corresponding to the outer peripheral surplus region 230, thereby forming an annular reinforcing portion 230b, as shown in FIG. 6.

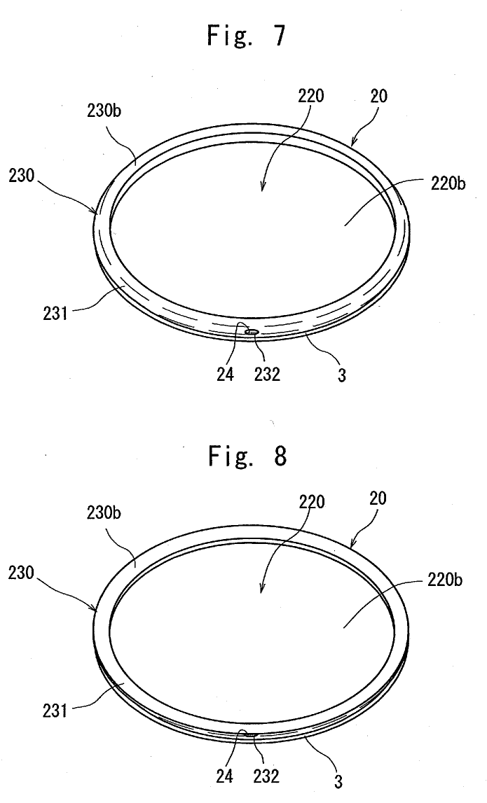

As described above, in the wafer substrate 20 having the annular reinforcing portion 230b formed at the outer peripheral portion of the back, all of the devices 22 formed in the device region 220 are present in the region corresponding to the circular concave portion 220b formed in the predetermined thickness. Thus, the devices 22 formed in the device region 220 do not exist at the position corresponding to the annular reinforcing portion 230b. Hence, all the devices 22 can be obtained as products, so that the yield rate can be increased. As noted here, in the wafer substrate 20 of the semiconductor wafer 2 subjected to the reinforcing portion forming step, the region corresponding to the outer peripheral surplus region 230 remains as the annular reinforcing portion 230b, as shown in FIG. 7. Thus, the identification code 24 printed on the flat surface 232 as the crystal orientation recognition mark formed in the outer peripheral end portion of the outer peripheral surplus region 230 remains without disappearing. Consequently, the identification code 24 can be confirmed.

If the above-mentioned reinforcing portion forming step is carried out from a state where the thickness of the wafer substrate 20 is, for example, 700 μm, a considerable operating time is needed. Hence, the reinforcing portion forming step may be performed after the back 20b of the wafer substrate 20 is ground throughout to bring the thickness to a half, 350 μm, for example. In this case, the thickness of the wafer substrate 20 is halved, as shown in FIG. 8, and a half of the flat surface 232 as the crystal orientation recognition mark formed in the outer peripheral end portion of the outer peripheral surplus region 230 is ground away. However, if the identification code 24 is printed in a range from the center of the flat surface 232 in the thickness direction of the wafer substrate 20 toward the face 20a, as shown in FIG. 2(b), the identification code 24 remains and can be confirmed.

The semiconductor wafer 2 subjected to the reinforcing portion forming step in the above manner has the annular reinforcing portion 230b removed by a suitable cutting step, and is further transported to a dividing step in which the devices 22 formed in the device region 220 are divided along the streets 21.

What is claimed is:

1. A wafer having a device region, where a plurality of devices is formed, and an outer peripheral surplus region, which surrounds the device region, on a face of a circular wafer substrate,
wherein a chamfered portion whose cross-sectional shape defines an arc-shaped surface in a range from the face to a back of the wafer substrate is formed in an outer peripheral end portion of the outer peripheral surplus region of the wafer substrate,
a flat surface orthogonal to the face and the back is formed in the chamfered portion as a mark showing crystal orientation of the wafer substrate, and
an identification code for specifying the wafer substrate is printed on the flat surface.

2. The wafer according to claim 1, wherein the identification code is printed on the flat surface in a region between the center and the face side in a thickness direction of the wafer substrate.
